(19) United States
(12) Patent Application Publication
(10) Pub. No.: US 2015/0129947 A1
(43) Pub. Date: May 14, 2015

(54) NONVOLATILE SEMICONDUCTOR STORAGE DEVICE

(71) Applicant: KABUSHIKI KAISHA TOSHIBA, Minato-ku (JP)

(72) Inventors: Satoshi NAGASHIMA, Yokkaichi (JP); Hideyuki YAMAWAKI, Yokkaichi (JP); Tatsuhiro ODA, Yokohama (JP); Tatsuya FUKUMURA, Yokkaichi (JP)

(73) Assignee: KABUSHIKI KAISHA TOSHIBA, Minato-ku (JP)

(21) Appl. No.: 14/187,772

(22) Filed: Feb. 24, 2014

Related U.S. Application Data
(60) Provisional application No. 61/903,460, filed on Nov. 13, 2013.

(51) Int. Cl. H01L 27/115

(52) U.S. Cl. CPC H01L 27/11551; H01L 27/11578
USPC 257/314

(57) ABSTRACT

A nonvolatile semiconductor storage device includes a NAND string including memory cells disposed in a first direction and a select gate disposed first-directionally adjacent to a first memory cell located at an end of the memory cells. A first gap is disposed between the memory cells and a second gap is disposed between the first memory cell and the select gate. Further, in a cross sectional shape, an upper end of the second gap is higher than an upper end of a first gap and an upper portion of the second gap is curved.

### CROSS-REFERENCE TO RELATED APPLICATION(S)

This application is based upon and claims the benefit of priority from U.S. Provisional Patent Application No. 61/903,460, filed on, Nov. 13, 2013 the entire contents of which are incorporated herein by reference.

### DESCRIPTION OF RELATED ART

1. Field

Embodiments disclosed herein generally relate to a nonvolatile semiconductor storage device.

2. Background

It is a generally required to reduce the chip size in nonvolatile semiconductor storage devices such as a NAND flash memory. This is often achieved by reducing the length of the so-called NAND string. Reducing the distance between the memory cell and the select gate is effective in reducing the length of the NAND string. However, reducing the distance between the memory cell and the select gate may increase the amount of leakage current occurring between the memory cell and the select gate.

### BRIEF DESCRIPTION OF THE DRAWINGS

FIG. 1 is one example of a block diagram schematically illustrating an electrical configuration of a memory cell block provided in a NAND Flash memory device of one embodiment.

FIG. 2 is one schematic example of a planar layout of memory cell region M in part.

FIGS. 3A and 3B are examples of vertical cross sectional views schematically illustrating a NAND Flash memory device of one embodiment.

FIG. 4A is one schematic example of an enlarged cross sectional view of air gap AG1, whereas FIG. 4B is one schematic example of an enlarged cross sectional view of air gap AG2.

FIGS. 5A to 5C are schematic examples of cross sectional views illustrating, in chronological order, the formation of insulating film 22 near select gate SG.

FIGS. 6A to 14A and FIG. 6B to 14B each exemplifies one phase of the manufacturing process flow of a NAND flash memory device of one embodiment.

FIG. 15 is one example of a plan view of a hook-up portion for word line WL.

### DETAILED DESCRIPTION

In one embodiment, a nonvolatile semiconductor storage device includes a NAND string including memory cells disposed in a first direction and a select gate disposed first-directionally adjacent to a first memory cell located at an end of the memory cells. A first gap is disposed between the memory cells and a second gap is disposed between the first memory cell and the select gate. Further, in a cross sectional shape, an upper end of the second gap is higher than an upper end of a first gap and an upper portion of the second gap is curved.

### First Embodiment

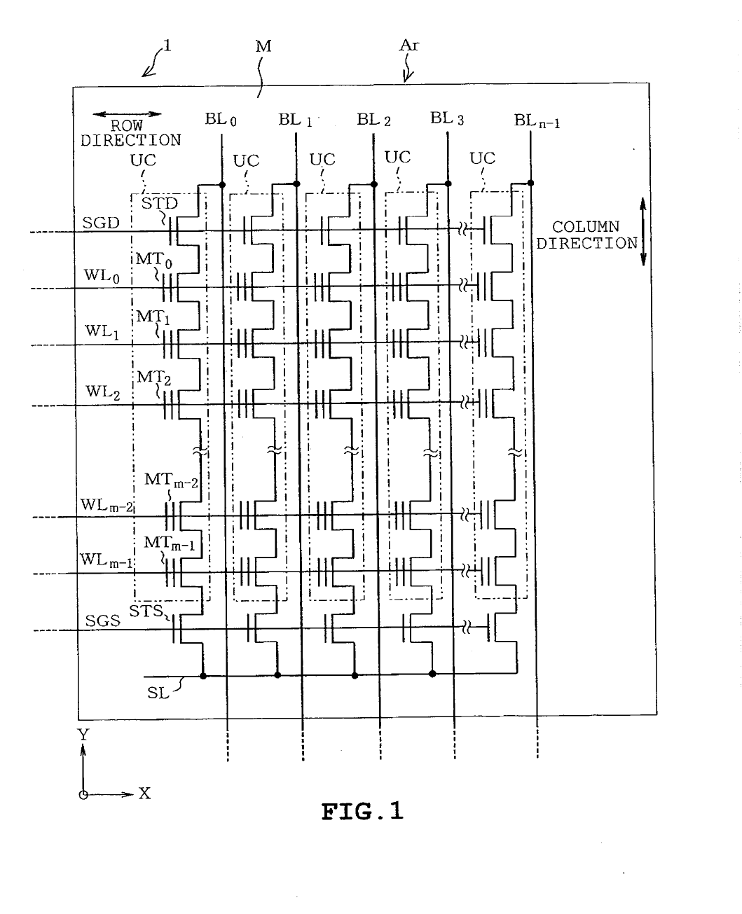

A first embodiment of a nonvolatile semiconductor storage device is described hereinafter through a NAND flash memory device application with references to FIG. 1 to FIG. 15. In the following description, elements that are identical in function and structure are identified with identical reference symbols. The drawings are not drawn to scale and thus, do not reflect the actual measurements of the features such as the correlation of thickness to planar dimensions and the relative thickness of different layers. Further, directional terms such as up, down, lower, left, and right are used in a relative context with an assumption that the surface, on which circuitry is formed, of the later described semiconductor substrate faces up. Thus, the directional terms do not necessarily correspond to the directions based on gravitational acceleration. In the following description, XYZ orthogonal coordinate system is used for ease of explanation. In the coordinate system, the X direction and the Y direction indicate directions parallel to the surface of a semiconductor substrate and are orthogonal to one another. The X direction indicates the direction in which word line WL extends, and the Y direction, being orthogonal to the Y direction, indicates the direction in which bit line BL extends. The embodiment is described based on NAND flash memory which is one example of a nonvolatile semiconductor storage device and references to interchangeable technologies will be made whenever applicable.

FIG. 1 is one example of a schematic diagram illustrating an electrical configuration of memory cell blocks of a NAND flash memory device. As shown in FIG. 1, NAND flash memory device 1 primarily comprises memory cell array Ar configured by multiplicity of memory cells arranged in a matrix.

Memory cell array Ar located in memory cell region M includes multiplicity of unit memory cells UC. Unit memory cells UC includes select transistors STD connected to bit lines BL₀ to Blₙ₋₁ and select transistors STS connected to source lines SL. Between select transistors STD and STS, m (m=2^{k}, for example) number of series connected memory-cell transistors MT₀ to MTₘ₋₁, disposed between select transistors STD and STS.

Unit memory cells UC constitute a memory-cell block and a plurality of memory-cell blocks constitute memory cell array Ar. A single block comprises n number of unit memory cells UC, aligned along the row direction (the left and right direction as viewed in FIG. 1). Memory cell array Ar constitutes a plurality of blocks aligned along the column direction (the up and down direction as viewed in FIG. 1). FIG. 1 only shows one block for simplicity.

The gates of select transistors STD are connected to control line SGD. The control gates of the m^{th} memory-cell transistors MTₘ₋₁ connected to bit lines BL₀ to Blₙ₋₁ are connected to word line WLₘ₋₁. The control gates of the third memory-cell transistors MT₂ connected to bit lines BL₀ to Blₙ₋₁ are connected to word line WL₂. The control gates of second memory-cell transistors MT₁ connected to bit lines BL₀ to Blₙ₋₁ are connected to word line WL₁. The control gates of first memory-cell transistors MT₀ connected to bit lines BL₀ to Blₙ₋₁ are connected to word line WL₀. The gates of select transistors STS connected to source lines SL are connected to control line SGS. Control lines SGD, word lines WL₀ to WLₘ₋₁, control lines SGS and source lines SL each intersect with bit lines BL₀ to Blₙ₋₁. Bit lines BLₒ to Blₙ₋₁ are connected to a sense amplifier not shown.

Gate electrodes of select transistors STD of the row-directionally aligned unit memory cells UC are electrically connected by common control line SGD. Similarly, gate electrodes of select transistors STS of the row directionally aligned unit memory cells UC are electrically connected by common control line SGS. The source of each select transistor STS is connected to common source line SL. Gate electrodes of memory-cell transistors MT₀ to MTₘ₋₁ of the row-directionally aligned unit memory cells UC are each electrically connected by word line WL₀ to WLₘ₋₁, respectively.

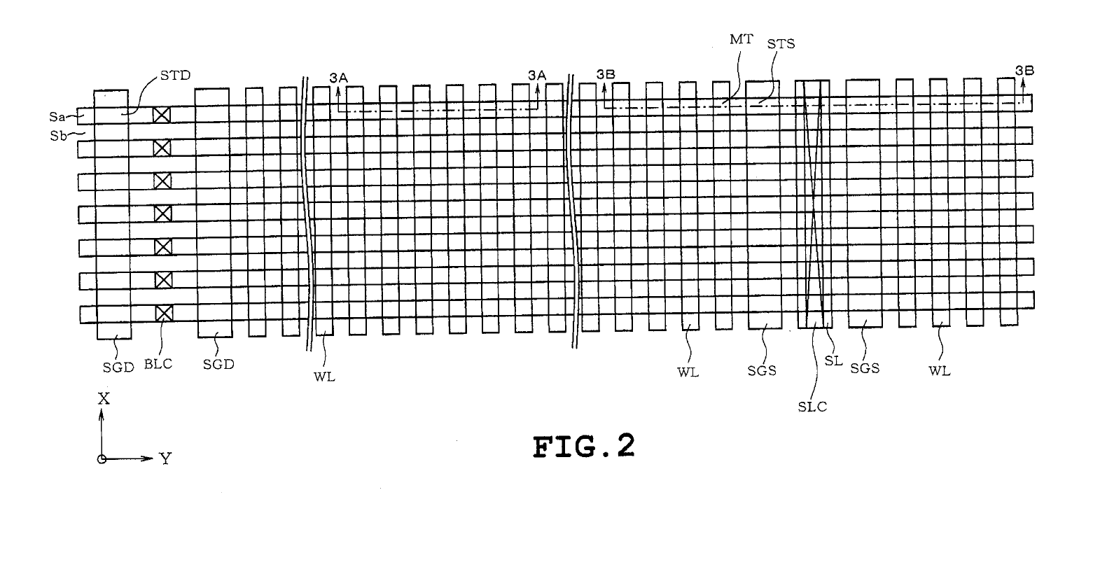

FIG. 2 is one schematic example of a planar layout of memory cell region M in part. Word lines WL₀ to WLₘ₋₁ and memory-cell transistors MT₀ to MTₘ₋₁ are also hereinafter referred to as word line (s) WL, and memory-cell transistor (s) MT for simplicity.

As shown in FIG. 2, source line SL, control line SGS, and control line SGD each run in the X direction (the Row Direction indicated in FIG. 1) and are spaced from one another in the Y direction (the Column Direction indicated in FIG. 1).

Element isolation regions Sb run in the Y direction. The element isolation region Sb takes an STI (shallow trench isolation) structure in which the trench is filled with an insulating film. Element isolation regions Sb are spaced from one another in the X direction by a predetermined distance. Thus, element isolation regions Sb isolate element regions Sa, formed in a surface layer of semiconductor substrate 2 along the Y direction, in the X direction. In other words, element isolation region Sb is located between element isolation regions Sa, meaning that the semiconductor substrate, is delineated into element regions Sa by element isolation region Sb. Bit lines BL not shown are aligned along the Y direction so as to be disposed above element regions Sa and isolated from one another by a predetermined distance. Bit lines BL are connected to element regions Sa via bit line contacts BLC.

Word lines WL extend in a direction orthogonal to element regions Sa (the X direction as viewed in FIG. 2). Word lines WL are spaced from one another in the Y direction by a predetermined distance. Above element region Sa located at the intersection with word line WL, memory-cell transistor MT is disposed. The Y-directionally adjacent memory-cell transistors MT constitute a part of a NAND string also referred to as a memory-cell string

Above element region Sa located at the intersection with control lines SGS and SGD, select transistors STS and STD are disposed. Select transistors STS and STD are disposed Y-directionally adjacent to the outer sides of memory cell transistors MT (memory cell MG1) located at both ends of the NAND string.

Select transistors STS connected to source line SL are aligned in the X direction and gate electrodes of select transistors STS are electrically interconnected by control line SGS. The gate electrode of select transistor STS is formed above element region Sa intersecting with control line SGS. Source contact SLC is provided at the intersection of source line SL and bit line BL.

Select transistors STD are aligned in the X direction and gate electrodes of select transistors STD are electrically interconnected by control line SGD. The gate electrode of select transistor STD is formed above element region Sa intersecting with control line SGD. Bit line contact BLC is provided in element region Sa located between the adjacent select transistors STD.

The foregoing description outlines the basic structures of NAND flash memory device of the first embodiment.

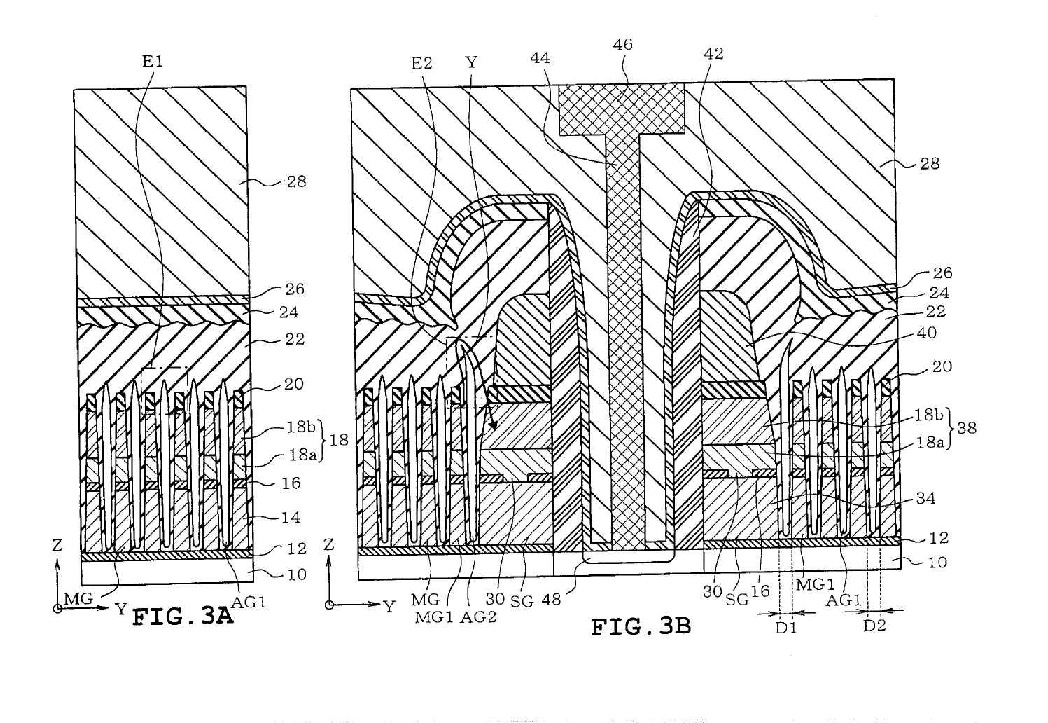

The structures of the first embodiment will be described in detail with reference to FIGS. 3A and 3B. FIGS. 3A and 3B are examples of vertical cross sectional views schematically illustrating the structures of NAND flash memory device 1 of the first embodiment. FIG. 3A is one example of a cross sectional view of a cross sectional structure taken along line 3A-3A of FIG. 2. FIG. 3B is one example of a cross sectional view of a cross sectional structure taken along line 3B-3B of FIG. 2.

FIG. 3A illustrates the cross sectional structure of a memory cell region.

Referring to FIG. 3A, memory cells MG are provided above semiconductor substrate 10. A silicon substrate having a P conductivity type may be used as semiconductor substrate 10. Above semiconductor substrate 10, gate insulating film 12 is formed which may, for example, be formed of a silicon oxide film obtained by thermally oxidizing semiconductor substrate 10 (silicon substrate).

Above gate insulating film 12, memory cell MG is formed by stacking charge storing layer 14, interelectrode insulating film 16, and control electrode 18. Charge storing layer 14 may, for example, be formed of a polysilicon (first polysilicon film 14a) doped with impurities. Examples of impurities include phosphorous, boron, or the like. Examples of interelectrode insulating film 16 include an ONO (Oxide/Nitride/Oxide) film, for example, formed of a silicon oxide film, a silicon nitride film, and a silicon oxide film stacked one over the other; and a structure including a polysilicon and a trap layer such as HfO stacked one over the other. Control electrode 18, for example, formed of a polysilicon (second polysilicon film 18a) doped with impurities and metal film 18b stacked above second polysilicon film 18a. Second polysilicon film 18a may be doped with impurities such as phosphorous or boron. Metal film 18b may, for example, formed of tungsten (W) formed by sputtering. Metal film 18b may include a barrier metal film in its lower portion, in other words, at the contacting interface with second polysilicon film 18a. The barrier metal film may, for example, be formed of tungsten nitride (WN) formed, for example, by sputtering. In such case, metal film 18b may, for example, be formed of a stack of tungsten nitride and tungsten. The barrier metal film is used, for example, to prevent silicide reaction between polysilicon constituting second polysilicon film 18a and tungsten constituting metal film 18b. Interelectrode insulating film 16 is provided between charge storing layer 14 and control electrode 18. Charge storing layer 14 and control electrode 18 are insulated from one another by interelectrode insulating film 16.

Gaps exist between memory cells MG, and insulating film 22 for covering the gaps is formed so as to extend across the upper portions of memory cells MG. Because the upper portions of the gaps are enclosed by insulating film 22 acting like a lid, the gaps disposed between memory cells MG are air gaps AG1. Insulating film 22 may, for example, be formed of silicon oxide film formed by plasma CVD. Because insulating film 22 is formed under conditions providing poor coverage, air gap AG1 is not fully filled with insulating film 22. As a result, insulating film 22 may be formed in air gap Ag1 so as to extend along the sidewalls of memory cells MG. Air gap AG1 reduces the parasitic capacitance between memory cells MG.

Above insulating film 22, first interlayer insulating film 24, stopper film 26, and second interlayer insulating film 28 are disposed. First interlayer insulating film 24 and second interlayer insulating film 28 may be formed of a silicon oxide film formed by CVD using TEOS (tetraethoxysilane), for example, as a source gas. Stopper film 26 may be formed of a silicon nitride film formed, for example, by CVD.

FIG. 3B illustrates one example of a portion taken along line 3B-3B of FIG. 2, in other words, a cross sectional structure of adjacent unit memory cells UC. More specifically, FIG. 3B illustrates one example of a cross section taken along select transistor STS and memory cells MG of each of unit memory cells UC located adjacent to one another. Select gate transistor STD side of unit memory cells UC is structured in a similar manner. FIG. 3B shows a pair of select gates SG disposed above semiconductor substrate 10. In the Y directional sides of the pair of select gates SG, memory cells MG are disposed. The memory cell MG which is Y-directionally adjacent to select gate SG is hereinafter referred to as memory cell MG1. Above semiconductor substrate 10, gate insulating film 12 is formed. The structure of memory cell MG illustrated in FIG. 3B is substantially identical to memory cell MG described based on FIG. 3A. Select gate SG includes a stack of lower electrode 34, interelectrode film 16, and upper electrode 38 disposed above gate insulating film 12. Lower electrode 34 comprises first polysilicon film 14a. Upper electrode 38 comprises second polysilicon film 18a and metal film 18b stacked above second polysilicon film 18a. Metal film 18b may include a barrier metal film in its lower portion, in other words, at the contacting interface with second polysilicon film 18a as was the case for memory cell MG.

Interelectrode insulating film 16 is disposed between lower electrode 34 and upper electrode 38. Interelectrode insulating film 16 has opening 30 located at the Y-directional center of the select gate SG. Lower electrode 34 and upper electrode 38 are electrically connected through opening 30. Cap insulating film 20 is formed above upper electrode 38. Mask insulating film 40 is formed above cap insulating film 20. The select gate stack comprises select gate SG, cap insulating film 20, and mask insulating film 40 and thus, is higher than the stacked structure of memory cell MG and cap insulating film 20 by the thickness of mask insulating film 40 added in select gate SG.

Gaps exist between memory cell MG1 and select gate SG and insulating film 22 for covering the gaps is formed so as to extend across the upper portions of memory cell MG1 and select gate SG. Because the upper portions of the gaps are enclosed by insulating film 22 acting like a lid, the gaps disposed between memory cell MG1 and select gate SG are air gaps AG2. The height of the upper edge of air gap AG2 is higher than the height of the upper edge of air gap AG1. The distance d1 between memory cell MG and select gate SG in the Y direction at the height of the bottom surface of memory cell MG (the bottom surface portion of charge storing layer 14) is equal to or narrower (less) than the distance d2 between the adjacent memory cells MG in the Y direction.

Above interlayer insulating film 22, first interlayer insulating film 24, stopper film 26, and second interlayer insulating film 28 are disposed. Between a pair of select gates SG, contact 44 is formed. Sidewall insulating film 42 is formed in contact with the sidewalls of insulating film 22, mask insulating film 40, and select gate SG. The lower portion of contact 44 is connected to semiconductor substrate 10. Wiring 46 is disposed above semiconductor substrate 10. As will be later described, contact 44 and wiring 46 of the first embodiment are formed by dual damascene method and thus, are formed in one. In semiconductor substrate 10 at the lower portion of contact 44 source/drain region 48 is formed which is doped with impurities such as phosphorous and arsenic.

Next, a description will be given on the cross sectional shapes of air gaps AG1 and AG2 illustrated in the figures. Air gap AG1 extends in an elongate shape in the Z direction. Air gap AG1 is substantially line-symmetric in the left and right direction (Y direction). Air gap AG2 is higher than air gap AG1. Air gap AG1 is asymmetric in the up and down direction (Z direction). The lower portion of air gap AG1 runs substantially along the surface profile of adjacent memory cell MG and semiconductor substrate 10 (gate insulating film 12) and is nearly rectangular.

Air gap AG2 is asymmetrical both in up and down direction (Z direction) and the left and right direction (Y direction). The lower portion of air gap AG2 is nearly rectangular in shape as was the case for air gap AG1. The upper portion of air gap AG2 is bent toward memory cell MG (in the direction opposite of select gate SG).

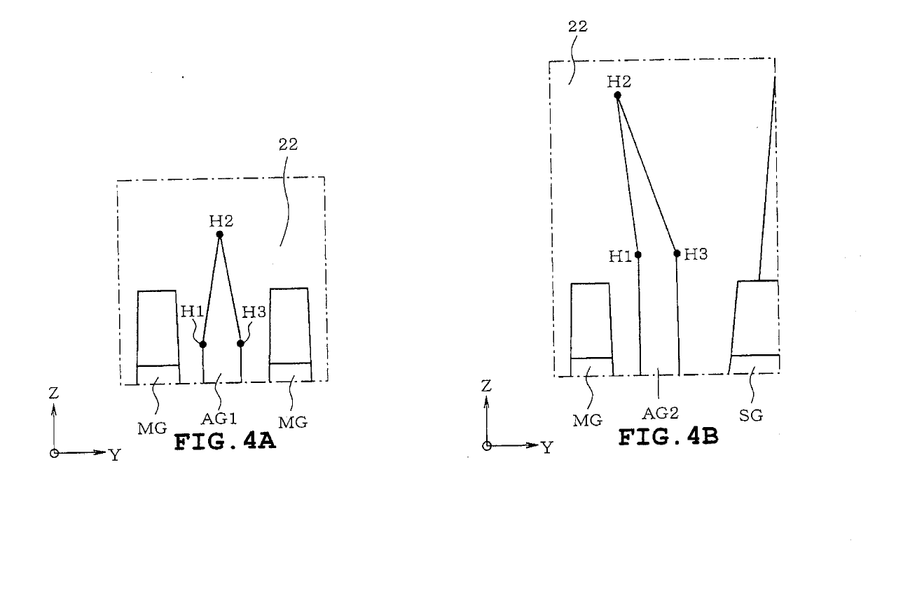

Next, a description will be given on the shape of the upper portion of air gaps AG1 and AG2. FIG. 4A is one example of an enlarged cross sectional view schematically illustrating the shape of the upper portion of air gap AG1. FIG. 4B is one example of an enlarged cross sectional view schematically illustrating the shape of the upper portion of air gap AG2. FIG. 4A is an enlarged view of region E1 illustrated in FIG. 3A, whereas FIG. 4B is an enlarged view of region E2 illustrated in FIG. 3B. As shown in FIGS. 4A and 4B, air gaps AG1 and AG2 are shaped so that their upper portions each have three or more inflection points though only three are shown as inflection points H1, H2, and H3.

In the upper edge of the upper portion of air gap AG1, the gap is enclosed by insulating film 22 deposited over the stacked structures of adjacent memory cell (memory cell MG1). The upper edge of the gap (the portion where inflection point H2 being the highest in elevation in the Z direction among the inflection points) terminates into a pointed tip. In the upper edge of air gap AG2, the gap is enclosed by insulating film 22 deposited over the stacked structures of adjacent memory cell and the stacked structures of select gate. The upper edge of the gap (the portion where inflection point H2 being the highest in elevation in the Z direction among the inflection points) terminates into a pointed tip. Inflection point H2 (the tip portion of the gap) of air gap AG2 is higher in elevation taken along the Z direction than inflection point H2 of air gap AG1 and is displaced in the Y direction toward memory cell MG 1 from the midpoint between memory cell MG1 and select gate SG. Inflection point H2 of air gap AG2 may be located above the stacked structure of memory cell which is Y-directionally adjacent to select gate SG. Inflection point H2 of air gap AG2 is located Z-directionally below a portion of stopper film 26 which rises up from the planar portion of stopper film 26.

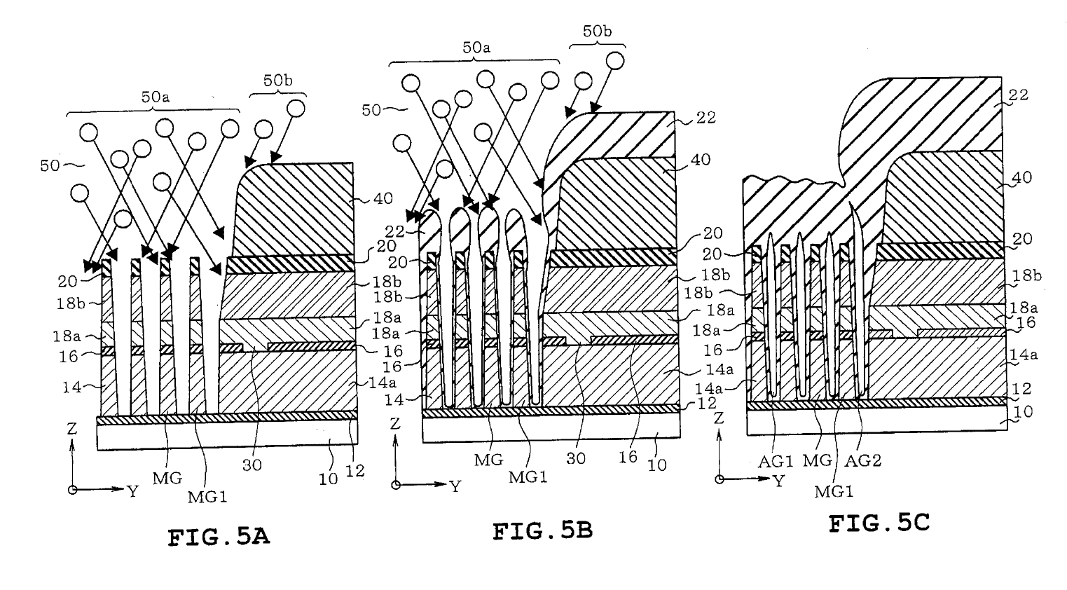

The above described shaped is believed to result because insulating film 22 is formed in the following manner. FIGS. 5A to 5C are examples of vertical cross sectional views schematically illustrating, in chronological order, how insulating film 22 is formed near select gate SG. Elements illustrated in FIGS. 5A to 5C that are identical to those illustrated in FIG. 3B are identified by identical reference symbols and are not re-described.

FIG. 5A illustrates the deposition of insulating film 22 being initiated. Insulating film 22 is formed by using, for example, TEOS as a source gas which is decomposed by plasma, generated within a reaction chamber of a manufacturing apparatus, to produce deposits of deposit particles 50 of silicon oxide film. Deposit particles 50 deposit over the surface of memory cell MG or select gate SG from various directions. For ease of explanation, only deposit particles 50 that descend obliquely (oblique component) relative to the Z direction are shown. Mask insulating film 40 is disposed above select gate SG and thus, select gate stack is higher than the stacked structure of memory cell by the thickness of mask insulating film 40. Thus, among deposit particles 50, the oblique component deposit particles 50 (50b) that transport from the upper right to the lower left of the ZY plane is blocked by mask insulating film 40 overlying select gate SG and thus, do not easily deposit over the surface of memory cell MG1. Deposit particles 50 are hardly deposited especially over the sidewall of memory cell MG1 facing select gate SG. On the other hand, the oblique component deposit particles 50 (50a) that transport from the upper left to the lower right of the ZY plane deposit in large amounts over the sidewall of mask insulating film 40 facing memory cell MG1. As a result, a thick insulating film 22 protruding toward memory cell MG1 is formed on the sidewall portion of mask insulating film 40 as shown in FIG. 5B. Thus, deposit particles 50, being blocked by the insulating film 22 formed over the sidewall portion of mask insulating film 40, are hardly deposited over the sidewall of memory cell MG1 facing select gate SG. As a result, deposit particles 50 depositing over memory cell MG1 located beside select gate SG leaves a deposition trajectory that curves leftward (in the direction opposite of select gate SG) in the Y direction. Because deposit particles 50 are deposited in relatively small amounts between memory cell MG1 and select gate SG, by the blocking effect discussed earlier, the gap beside select gate SG extend further upward in the Z direction compared to the gap between memory cells MG. Because deposit particles 50 are deposited in relatively large amounts over the sidewalls of mask insulating film 40 overlying select gate SG, the gap beside select gate SG is formed so as to curve toward memory cell MG1 (leftward toward as viewed in FIG. 5B in the direction opposite select gate SG). As the deposition of deposit particles 50 further progresses, the upper portions of the gaps between the adjacent memory cells MG and between memory cell MG1 and select gate SG are enclosed by insulating film 22 as shown in FIG. 5C to form air gaps AG1 and AG2. Air gap AG2 is curved toward memory cell MG1 and the upper edge of air gap AG2 is higher in elevation than the upper edge of air gap AG1. Because deposit particles 50 deposit almost in equal amounts between memory cells MG, the shape of the resulting air gap AG1 is substantially symmetrical in the left and right direction.

The above described shape of air gaps AG1 and AG2 provide the following effects. Most of insulation breakdown and leakage current in an air gap generally occur in the form of interface leakage in which the inner wall of the air gap serves as the leakage path. Thus, it is possible to inhibit insulation breakdown and leakage current more effectively by increasing the interface leakage path. In the first embodiment, it is possible to increase the distance of interface leakage path Y between memory cell MG1 and select gate SG by increasing the height of air gap AG2 as shown in FIG. 3B. It is further possible to increase the interface leakage path Y by locating inflection point H2 of air gap AG2 above memory cell MG1. As a result, it is further possible to relax the electric field applied to the edges of the gate electrode of memory cell MG and select gate SG. In NAND flash memory devices, possibility of insulating film breakdown or leakage current is large during an erasing operation. Leakage current occurs even in a dummy cell in which memory cell MG1 is not used for data storage. This is because during the erasing operation, a large potential difference is produced between select gate SG and memory cell MG1 adjacent to select gate SG (for instance, 0V may be applied to memory cell MG1 and 10V may be applied to select gate SG). However, by adopting the above described structure, it is possible to improve breakdown voltage between memory cell MG1 and select gate SG. As a result, it is possible to reduce the distance between memory cell MG1 and select gate SG and consequently reduce the length of the NAND string. Stated differently, it is possible to achieve an air gap structure in which reduction of the breakdown voltage between memory cell MG1 and select gate SG is inhibited, by reducing the distance between memory cell MG1 and select gate SG intended to reduce the length of the NAND string.

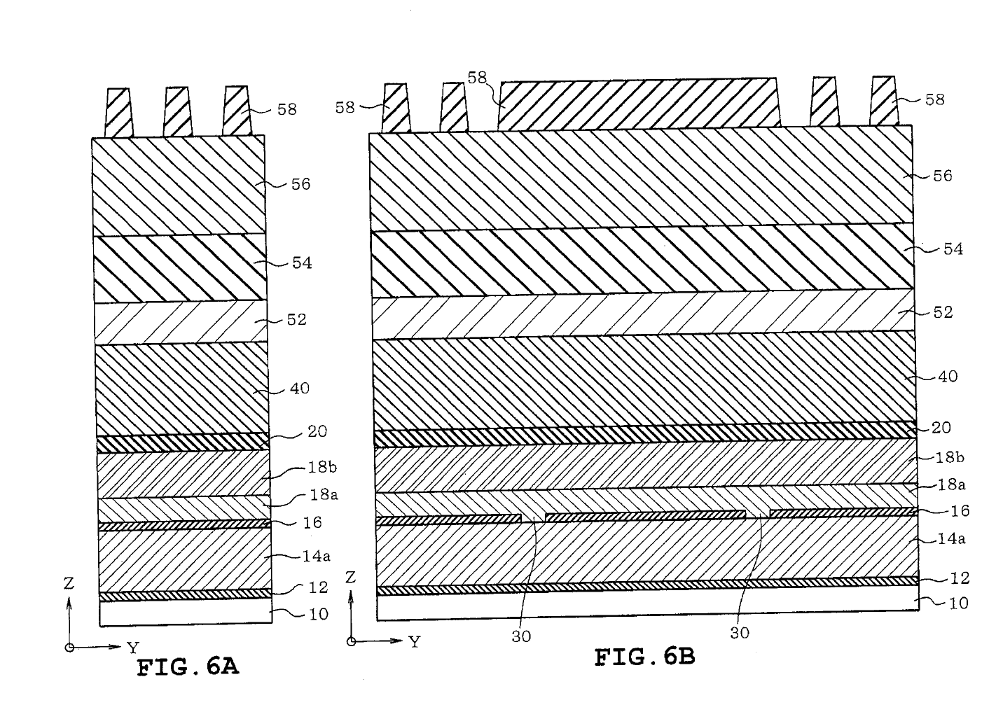

Next, a description is given on the process flow for manufacturing a semiconductor storage device of the first embodiment with reference to FIGS. 3A and 3B, FIGS. 6A and 6B to FIGS. 14A and 14B. FIGS. 6A and 6B to FIGS. 14A to 14B are cross sectional views illustrating examples of one phase of the manufacturing process flow of the first embodiment.

First, as shown in FIGS. 6A and 6B, resist 58 is formed above semiconductor substrate 10 having gate insulating film 12, first polysilicon film 14a, interelectrode insulating film 16, second polysilicon film 18a, metal film 18b, gap insulating film 20, mask insulating film 40, first mask film 52, second mask film 54, and third mask film 56 formed thereabove. A silicon substrate having a p-conductivity type, for example, may be used as semiconductor substrate 10. Gate insulating film 12 may, for example, be formed of a silicon oxide film formed by thermally oxidizing the surface of semiconductor substrate 10. First polysilicon film 14a may be formed, for example, by forming polysilicon by CVD (Chemical Vapor Deposition) and introducing impurities such as phosphorous or boron. Interelectrode insulating film 16 may, for example, be formed of an ONO film. The ONO film may be formed, for example, by forming silicon oxide film/silicon nitride film/silicon oxide film one over the other by, for example, CVD. Interelectrode insulating film 16 has through hole 30 formed in a portion where select gate SG is later formed. Second polysilicon film 18a may be formed, for example, by forming polysilicon by CVD and introducing impurities such as phosphorous or boron. Metal film 18b may be formed of tungsten which was formed, for example, by sputtering. When forming metal film 18b as a stack of a barrier metal film and a metal film, the barrier metal film may be formed, for example, by sputtering tungsten nitride and thereafter sputtering tungsten. Cap insulating film 20 may, for example, be formed of a silicon nitride film formed by CVD. Cap insulating film 20 may be formed of a silicon oxide film instead of a silicon nitride film. Mask insulating film 40 may, for example, be formed of a silicon oxide film formed by CVD. First mask film 52 may, for example, be formed of an amorphous silicon film formed by CVD. Second mask film 54 may, for example, be formed of a carbon film formed by CVD. Third mask film 56 may, for example, be formed of a silicon oxynitride film (SiON) formed by CVD. Resist 58 may be formed by coating resist over semiconductor substrate 10 in a predetermined thickness and patterning the resist by lithography.

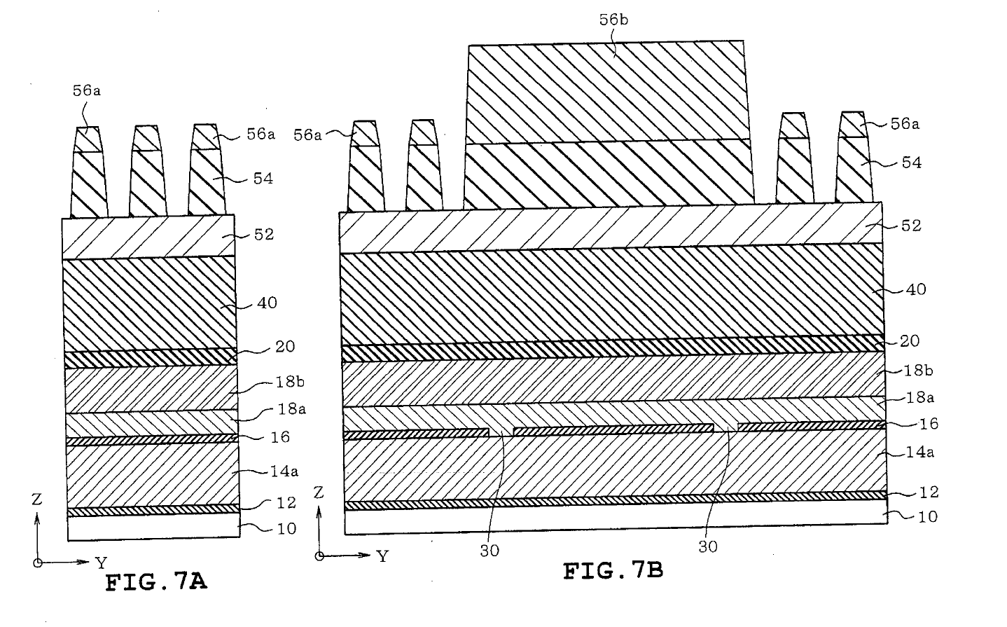

Next, as shown in FIGS. 7A and 7B, third mask film 56 and second mask film 54 are anisotropically etched by RIE (Reactive Ion Etching) using resist 58 as a mask. The etching initially progresses through the third mask film 56 using resist 58 as a mask. Resist 58 may be dissipated while the etching progresses through second mask film 54. Then, etching progresses through second mask film 54 using the patterned third mask film 56 as a mask and is terminated when the surface of first mask film 52 is exposed. The dimension of Y-directional pattern of third mask film 56a, located in the region where memory cell MG is later formed, is configured to be smaller than dimension of Y-directional pattern of third mask film 56b formed in the region where select gate SG is later formed. Patterns of small dimensions are easily etched by the micro-loading effect of etching. As a result, third mask film 56a is thinned while third mask film 56b is thickened.

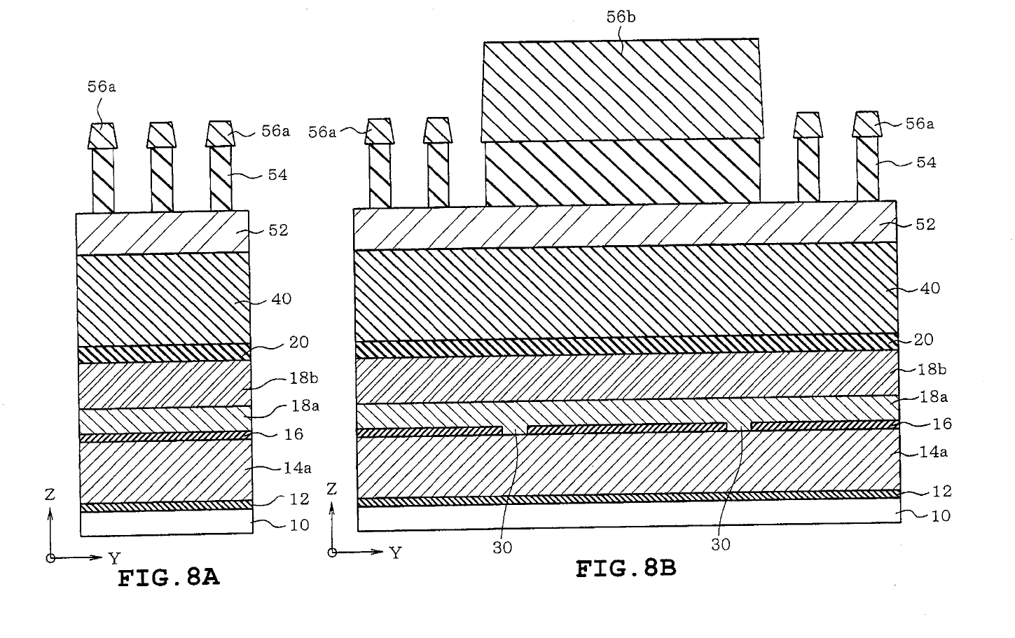

Next, second mask film 54 is slimmed as shown in FIGS. 8A and 8B. Second mask film 54 may be slimmed, for example, by isotropic dry etching using oxygen plasma. As described above, etching is performed, for example, by oxygen plasma when second mask film 54 is made of carbon. Thus, the lateral dimension of second mask film 54 is reduced. Etching is performed with low etch rates for third mask film 56 and first mask film 52. As a result, only second mask film 54 recedes while third mask film 56 and first mask film 52 hardly recede.

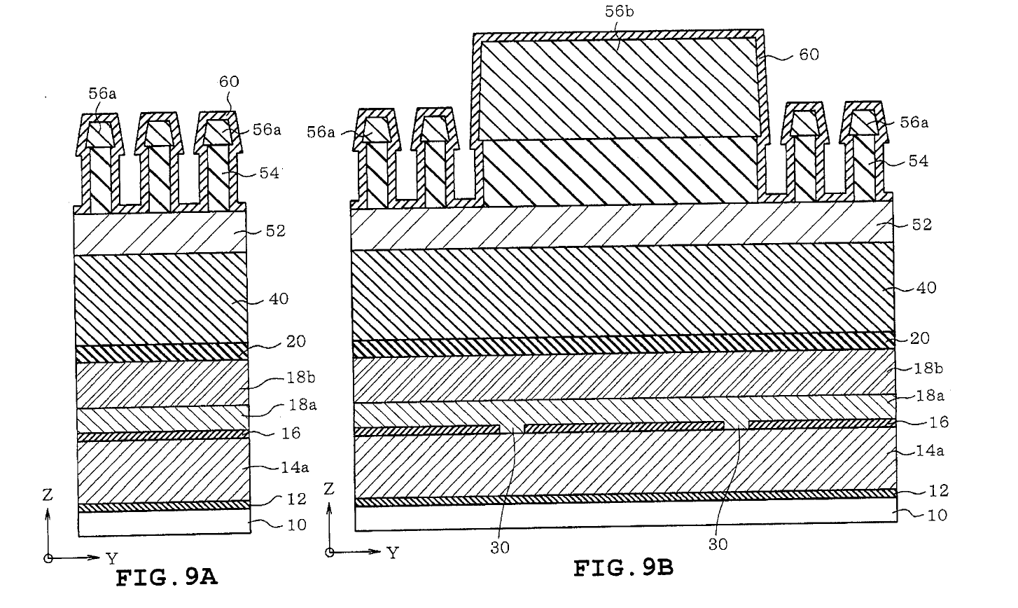

Next, as shown in FIGS. 9A and 9B, insulating film 60 is formed so as to cover third mask films 56a and 56b, second mask films 54, and first mask film 52. Insulating film 60 may, for example, be formed of a silicon oxide film. Insulating film 60 may be formed, for example, by CVD performed under conditions providing good coverage and low film forming temperature.

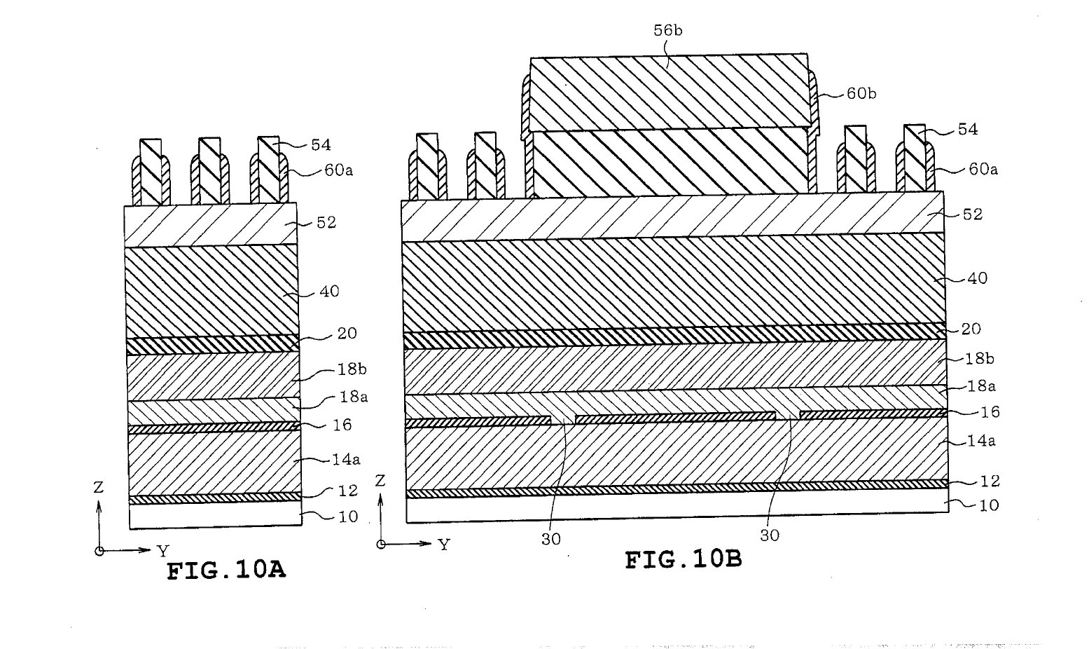

Next, as shown in FIGS. 10A and 10B, insulating film 60 is etched back to form insulating films 60a and 60b from insulating film 60 along the sidewalls of second mask film 54. Third mask film 56a and 56b are also etched during the etch back of insulating film 60. Because dimension of third mask film 56a is small, etch rate of third mask film 56a is increased by micro-loading effect and thus, dissipates with insulating film 60 during the etch back. Because dimension of third mask film 56b is large, third mask film 56b remains along second mask film 54 though being removed to some extent. Insulating film 60b is formed continuously along the sidewalls of third mask film 56b and second mask film 54. Second mask film 54, underlying third mask film 56b, is covered by third mask film 56b and insulating film 60b and thus, is not exposed.

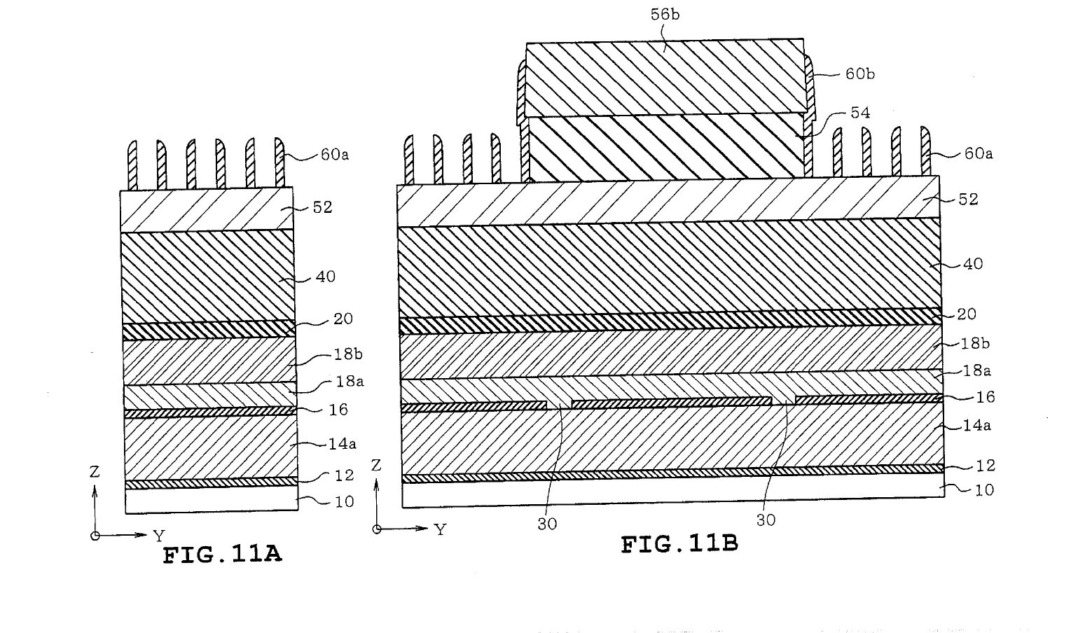

Next, second mask film 54 is selectively removed as shown in FIGS. 11A and 11B. Second mask film 54 (carbon) may be removed, for example, by oxygen plasma ashing. As a result, pillars of insulating film 60a are formed. Second mask film 54 remains below third mask film 56b.

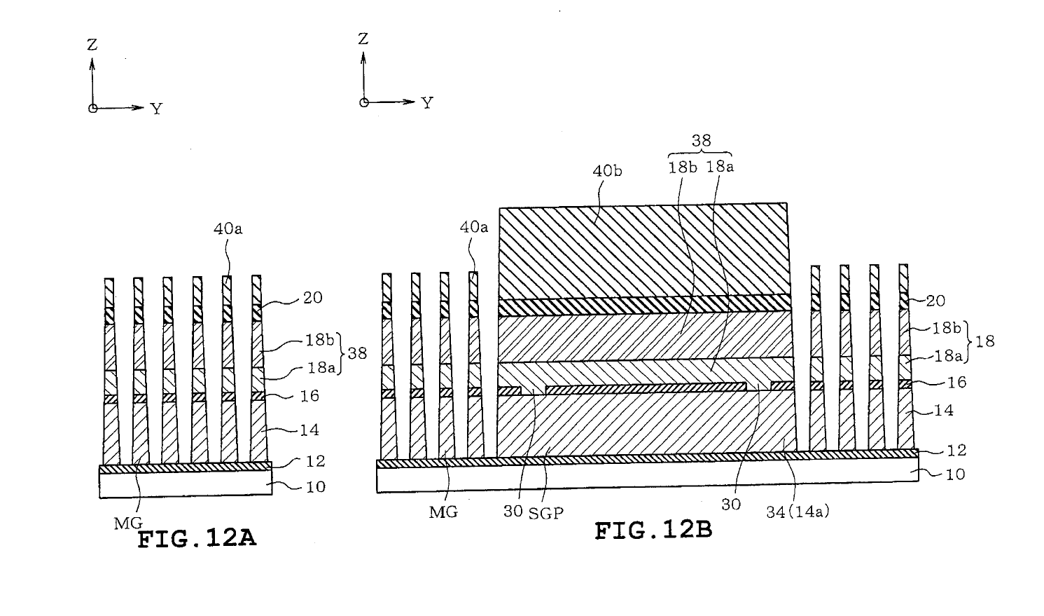

Next, using insulating film 60a and third mask film 56b as well as insulating film 60b disposed along the sidewalls of third mask film 56b as a mask, first mask film 52, mask insulating film 40, cap insulating film 20, metal film 18b, second polysilicon film 18a, interelectrode insulating film 16, and charge storing layer 14, are etched one after another as shown in FIGS. 12A and 12B. As a result, memory cells MG and pattern SGP, later formed into select gates SG, are formed. Etching progresses anisotropically under RIE method in varying conditions depending upon the etch target. The etching is stopped on gate insulating film 12. In case third mask film 56b dissipates during the etching, the underlying second mask film 54 serves as the etch mask. In case insulating films 60a and 60b (silicon oxide film) and second mask film 54 (carbon) are dissipated during the etching of mask insulating film 40 (silicon oxide film), the underlying first mask film 52 (amorphous silicon) serves as a mask for etching of mask insulating film 40. Because dimension of mask insulating film 40 disposed above memory cell MG (hereinafter represented by 40a) is small, mask insulating film 40a recedes during the etching by micro-loading effect and thereby thinned. Because dimension of mask insulating film 40 disposed above pattern SGP (hereinafter represented by 40b) is large, mask insulating film 40b does not easily recede during the etching and thus, remains thick. A thickness of mask insulating film 40a becomes thin and a thickness of mask insulating film 40b becomes thick as a result from the etching. This may be re-described as mask insulating film 40b being higher than mask insulating film 40a.

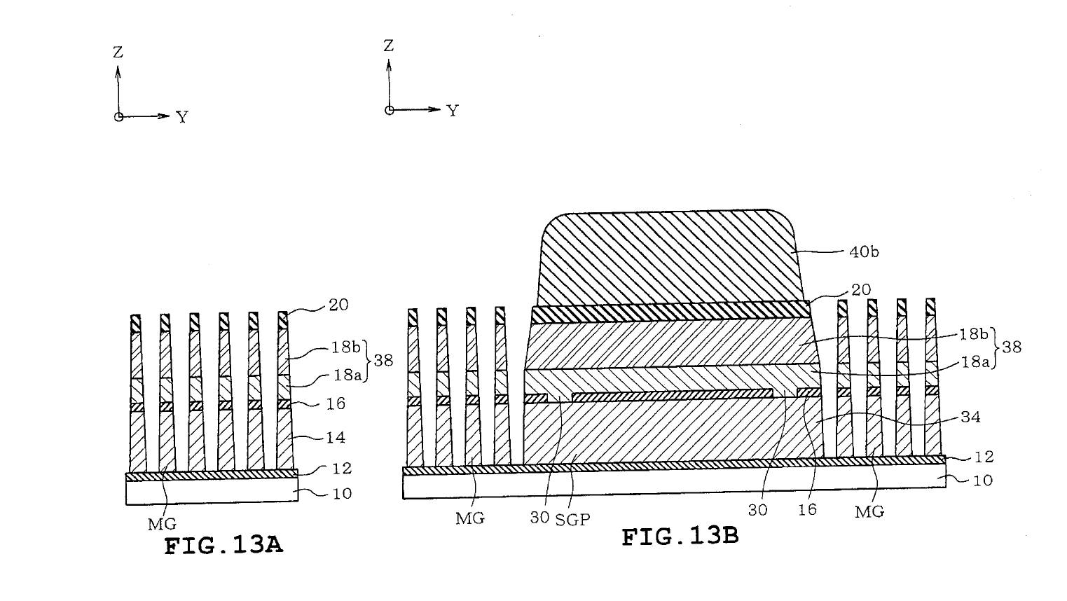

Next, as shown in FIGS. 13A and 13B, mask insulating film 40a is etched away using dilute hydrofluoric acid. At this instance, mask insulating film 40b also recedes isotropically. As a result, the interface between cap insulating film 20 and mask insulating film 40b may be stepped.

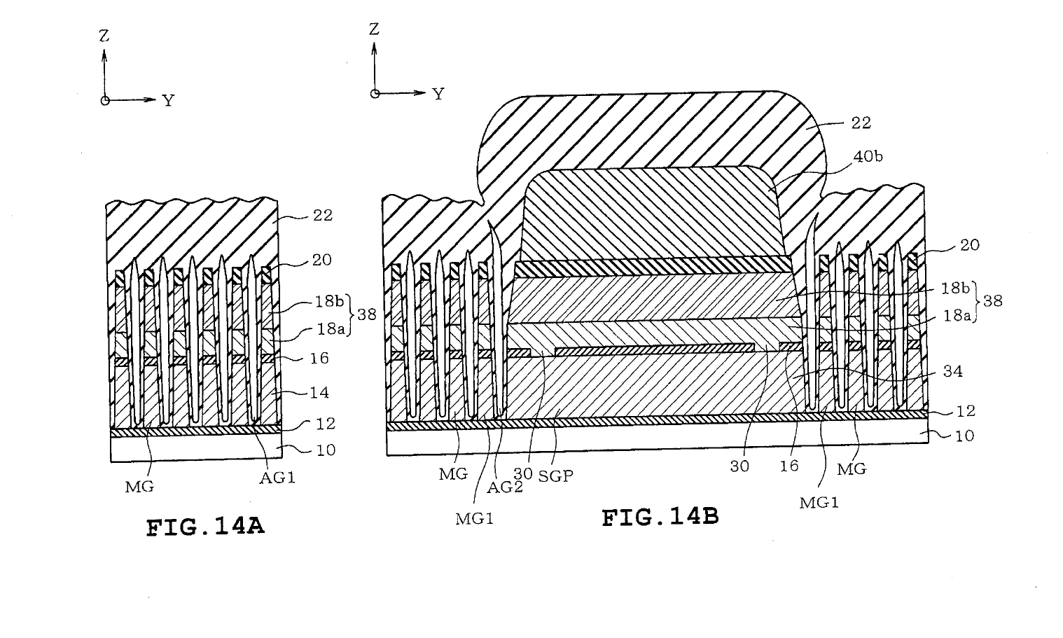

Next, as shown in FIGS. 14A and 14B, insulating film 22 is formed above memory cell GM and pattern SGP. Insulating film 22 may, for example, be formed of a silicon oxide film formed by plasma CVD under conditions providing poor coverage. It is thus, possible to form air gaps AG1 and AG2 by the above described process flow. The details insulating film 22 formation are as mentioned earlier with reference to FIGS. 5A to 5C. Because the upper end of air gap AG2 can be made higher than the upper end of air gap AG1, it is possible to reduce the leakage current between memory cell MG1 and select gate SG. Further, because the distance between memory cell MG1 and select gate SG can be reduced, it is possible to reduce the length of the NAND string.

Next, as shown in FIGS. 3A and 3B, first interlayer insulating film 24 is formed entirely over the underlying structure, whereafter the central portion of pattern SGP is removed by lithography and RIE. First interlayer insulating film 24 may be formed of a silicon oxide film formed by CVD using TEOS (tetraethoxysilane), for example, as a source gas. Then, after forming sidewall insulating film 42, stopper film 26 is formed, followed by formation of second interlayer insulating film 28, whereafter the entire surface is planarized by CMP (Chemical Mechanical Polishing). Sidewall insulating film 42, for example, is formed of a silicon nitride film. Second interlayer insulating film 28, for example, is formed of a silicon oxide film. Then, contact 44 and wiring 46 are formed, for example, by dual damascene method. The semiconductor device of the first embodiment may be formed by the above described process flow.

In the process step described with reference to FIGS. 12A, 12B, 13A, and 13B, mask insulating film 40a above memory cell MG was removed so as not to remain above memory cell MG. This is because in case mask insulating film 40a, being substantially as thick as the mask insulating film 40b disposed above pattern SGP, will cause air gap AG1 to be high as well.

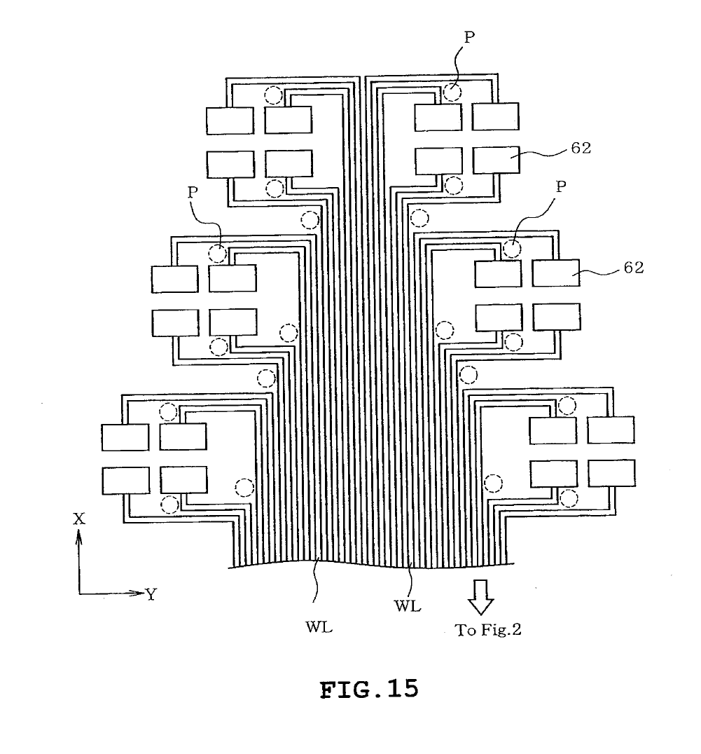

Next, a description will be given on a location where the highest air gap is formed. FIG. 15 is one example of a plan view illustrating the pattern of a hook-up region for word lines WL. In FIG. 15, word lines WL extend in the X direction, oriented upward in the view from the layout illustrated in FIG. 2, so as to have a predetermined space from one another in the Y direction. Word lines WL extending from FIG. 2 are routed so as to be bent in the Y direction to enable connection with pads 62. Circles P in FIG. 15 indicate portions where the spacing between word lines WL are suddenly increased. In case mask insulating film 40a, being as thick as mask insulating film 40b remaining above select gate SG, remains above memory cell MG, the upper end of air gap AG1 may become as high or higher than the upper end of air gap AG2 in the locations indicated by circles P. This is because the elevation in which insulating film 22 encloses the gaps becomes higher where the spacing is wide as compared to where the spacing is narrow. It is to be noted that the upper end of air gap AG1 located in memory cell region M is higher than the upper end of air gap AG1 located in the portion indicated by circle P. Because the height of air gap AG1 located in the portion indicated by circle P is high, polishing of second interlayer insulating film 28 by CMP earlier described with reference to FIGS. 3A and 3B may open the upper portion of air gap AG1. When the upper portion of air gap AG1 is opened, chemical liquids or the like may enter air gap AG1 through the opening in process steps such as the cleaning step and may remain as residue when drying of the chemical liquid which has entered air gap AG1 fails. Further, when metal materials used in process steps such as the wiring process enter air gaps AG1, wiring short may occur. Thus, mask insulating film 40a disposed above memory cell MG is preferably lowered as much as possible or removed to prevent the height of air gap AG1 located in the portion indicated by circle P from becoming high. Mask insulating film 40a disposed above memory cell MG need not be completely removed but may remain in a thickness that would provide sufficient difference in the thickness (difference in height) from mask insulating film 40b located above pattern SGP.

As described above, in the first embodiment, it is possible to improve the breakdown voltage between memory cell MG and select gate SG by increasing the height of air gap AG2. As a result, it is possible to reduce the distance between memory cell MG1 and select gate SG and reduce the length of NAND string. Thus, it is possible to realize a NAND flash memory device which is capable of reducing the chip size.

### Other Embodiments

The following modifications may be made to the embodiment described above.

ONO film is applied as one example of interelectrode insulating film 16. However, a NONON (nitride-oxide-nitride-oxide-nitride) film or an insulating film having high dielectric constant or the like may be applied instead.

Tungsten was used as one example of metal material constituting metal film 18b. However, tungsten may be replaced by aluminum (AL) or titanium (Ti).

The above described embodiment was described through an example of NAND flash memory application but other embodiments may be described through examples of other nonvolatile semiconductor storage devices such as NOR flash memory device or EEPROM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a NAND string including memory cells disposed in a first direction and a select gate disposed adjacent to a first memory cell located at an end of the memory cells in the first direction;
a first gap disposed between the memory cells; and
a second gap disposed between the first memory cell and the select electrode;
wherein, in a cross sectional shape along the first direction, an upper end of the second gap is higher than an upper end of a first gap and an upper portion of the second gap is curved.

2. The device according to claim 1, wherein, in a cross sectional shape taken along the first direction, the upper portion of the second gap is curved toward the first memory cell.

3. The device according to claim 1, wherein, in a cross sectional shape taken along the first direction, a bottom portion of the second gap is substantially rectangular, the upper portion of the second gap is curved toward the first memory cell, an upper end portion of the second gap is pointed.

4. The device according to claim 1, wherein, in a cross sectional shape taken along the first direction, the second gap includes three or more inflection points in the upper portion thereof.

5. The device according to claim 1, wherein, in a cross sectional shape taken along the first direction, a bottom portion of the first gap is substantially rectangular and a tip portion of an upper end portion of the first gap is pointed.

6. The device according to claim 1, wherein, in a cross sectional shape taken along the first direction, the first gap includes three or more inflection points in the upper portion thereof.

7. The device according to claim 1, wherein, in a cross sectional shape taken along the first direction, an upper end portion of the second gap is located above the first memory cell.

8. A nonvolatile semiconductor storage device comprising:
a NAND string including memory cells disposed in a first direction and a select gate disposed adjacent to a first memory cell located at an end of the memory cells in the first direction;
a first gap disposed between the memory cells; and
a second gap disposed between the first memory cell and the select gate;
wherein the memory cells each include a charge storing layer, and
wherein, in a cross sectional shape taken along the first direction, an upper end of the second gap is higher than an upper end of the first gap, and
wherein, when measured at a height of a bottom surface of the charge storing layer, a distance between the first memory cell and the select gate in the first direction is substantially equal to or less than a distance between the memory cells in the first direction.

9. The device according to claim 8, wherein, in a cross sectional shape taken along the first direction, the upper portion of the second gap is curved.

10. The device according to claim 8, wherein, in a cross sectional shape taken along the first direction, the upper portion of the second gap is curved toward the first memory cell.

11. The device according to claim 8, wherein, in a cross sectional shape taken along a first direction, a bottom portion of the second gap is substantially rectangular, an upper portion of the second gap is curved toward the first memory cell, a tip portion of the upper end portion of the second gap is pointed.

12. The device according to claim 8, wherein, in a cross sectional shape taken along the first direction, the second gap includes three or more inflection points in an upper portion thereof.

13. The device according to claim 8, wherein, in a cross sectional shape taken along the first direction, a bottom portion of the first gap is substantially rectangular and a tip portion of an upper end portion of the first gap is pointed.

14. The device according to claim 8, wherein, in a cross sectional shape taken along the first direction, the first gap includes three or more inflection points in an upper portion thereof.

15. The device according to claim 8, wherein, in a cross sectional shape taken along the first direction, an upper end portion of the second gap is located above the first memory cell.
